(19) United States
(12) Patent Application Publication
(10) Pub. No.: US 2017/0282419 A1
(43) Pub. Date: Oct. 5, 2017

(54) IMPRINT APPARATUS, METHOD OF IMPRINTING, METHOD FOR PRODUCING ARTICLE, AND MOLD

(71) Applicant: CANON KABUSHIKI KAISHA, Tokyo (JP)

(72) Inventors: Tatsuya Hayashi, Utsunomiya-shi (JP); Kazuki Nakagawa, Utsunomiya-shi (JP); Yosuke Murakami, Utsunomiya-shi (JP)

(21) Appl. No.: 15/473,477

(22) Filed: Mar. 29, 2017

(30) Foreign Application Priority Data
Apr. 5, 2016 (JP) 2016-075989

(51) Int. Cl. B29C 43/52; G03F 7/00; B29C 43/02

(52) U.S. Cl. CPC B29C 43/52; B29C 43/021; G03F 7/0002; B29K 2905/08

(57) ABSTRACT

An imprint apparatus for forming a pattern of an imprint material on a process area of a substrate by using a mold including a patterned portion includes a heating unit. The heating unit heats the substrate such that a difference in shape between the process area and the patterned portion is reduced and heats the mold such that a difference in temperature between the mold and the heated substrate is reduced.

### BACKGROUND OF THE INVENTION

### Field of the Invention

The present disclosure relates to an imprint apparatus, a method of imprinting, a method for producing an article, and a mold.

### Description of the Related Art

With the growing need for miniaturization of semiconductor devices and micro electro mechanical systems (MEMS), a microfabrication technique for molding an imprint material on a substrate using a mold to form a pattern of the imprint material on the substrate draws attention in addition to known photolithography. This technique is also referred to as an imprinting technique. With this technique, it is possible to form a fine structure on the order of several nanometers on a substrate. An example of the imprinting technique is a photo-curing method. An imprint apparatus that uses the photo-curing method first applies a photo-curable imprint material onto a shot area, which is an imprint area, on a substrate. Next, the imprint apparatus shapes the imprint material using a mold. Then, the imprint apparatus applies light, such as ultraviolent rays, to cure the imprint material and then releases the imprint material to form a resin pattern on the substrate.

In a series of device producing processes, the substrate can be expanded or contracted through a heating process in a deposition process, such as sputtering, to change in a shot area, which is formed in advance on the substrate, in the directions of two axes intersecting at right angles in the surface of the substrate. For that reason, when pressing the mold and the imprint material on the substrate together, the imprint apparatus needs to align the shape of the shot area and the shape of a patterned portion formed on the mold with each other.

An example of a technique for aligning the shape of the deformed shot area and the shape of the patterned portion with each other is disclosed in Japanese Patent Laid-Open No. 2013-102132. This discloses an imprint apparatus that deforms the shot area by heating the substrate.

In aligning the shape of the shot area and the shape of the patterned portion with each other, the shape of the shot area and the shape of the patterned portion are corrected, with the imprint material sandwiched between the mold and the substrate. When the thickness of the imprint material sandwiched between the mold and the substrate becomes the order of nanometers, the viscoelasticity of the imprint material, which is non-Newton fluid, increases, making it impossible to correct the shape of the shot area and the shape of the patterned portion. For that reason, it is necessary to correct the shape of the shot area and the shape of the patterned portion in a state in which the mold is not in contact with the imprint material applied on the substrate. In this case, after the shape of the shot area is corrected by heating, the mold and the imprint material applied on the substrate are brought into contact with each other, so that the heat of the substrate is absorbed in the mold via the imprint material to change the shape of the shot area, decreasing the alignment accuracy.

### SUMMARY OF THE INVENTION

The present disclosure provides an imprint apparatus, a method of imprinting, a method for producing an article, and a mold, in which a decrease in alignment accuracy is reduced.

An imprint apparatus according to an aspect of the present disclosure is an imprint apparatus for forming a pattern of an imprint material on a process area of a substrate by using a mold including a patterned portion. The imprint apparatus includes a heating unit configured to heat the mold and the substrate. The heating unit heats the substrate such that a difference in shape between the process area and the patterned portion is reduced and heats the mold such that a difference in temperature between the mold and the heated substrate is reduced.

Further features of the present invention will become apparent from the following description of exemplary embodiments with reference to the attached drawings.

### BRIEF DESCRIPTION OF THE DRAWINGS

FIG. 1 is a diagram illustrating the configuration of an imprint apparatus according to a first embodiment of the present disclosure.

FIG. 2 is a diagram illustrating the configuration and disposition of a heating mechanism 6 and so on of the imprint apparatus.

FIG. 3 is a flowchart of an imprinting process of the first embodiment.

FIG. 4A is a diagram illustrating the configuration of a mold of the first embodiment.

FIG. 4B is a diagram illustrating a shot area on a substrate of the first embodiment.

FIG. 5 is a diagram illustrating correction of the shapes of a patterned portion of the mold and the shot area on the substrate and their temperature distributions of the first embodiment.

FIG. 6 is a diagram illustrating the configuration and disposition of a mold heating mechanism of a second embodiment.

FIG. 7 is a flowchart for an imprinting process of the related art.

FIGS. 8A to 8F are diagrams illustrating a method for producing an article.

FIGS. 9A to 9D are diagrams illustrating another method for producing an article.

### DESCRIPTION OF THE EMBODIMENTS

Embodiments of the present disclosure will be described in detail hereinbelow with reference to the drawings. In the drawings, like components are given like reference numbers, and redundant descriptions will be omitted.

### First Embodiment

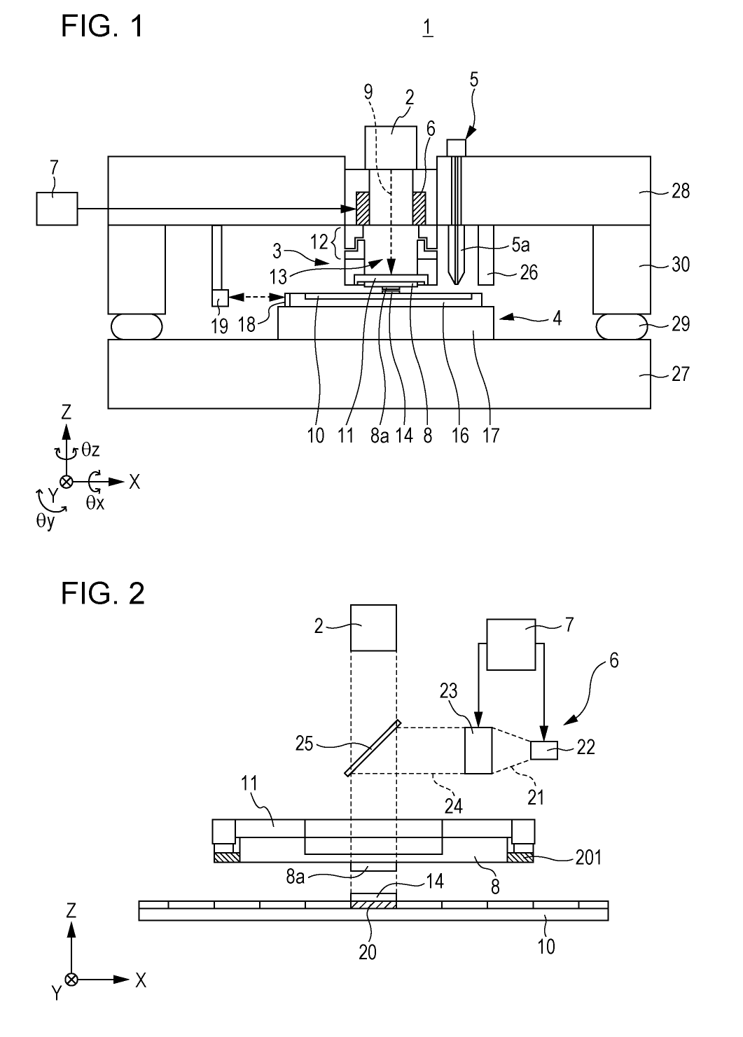

FIG. 1 is a diagram illustrating a representative example of an imprint apparatus. An imprint apparatus 1 is an apparatus that form a pattern of a cured material to which an embossed pattern of a mold is transferred by bringing a mold and an imprint material supplied onto a substrate into contact with each other and by giving energy for curing to the imprint material. In this embodiment, the imprint apparatus 1 is an imprint apparatus that employs a photo-curing method. In FIG. 1, a Z-axis is taken parallel to the optical axis of an illumination system that applies light to an imprint material 14 on a substrate 10, and an X-axis and a Y-axis intersecting at right angles are taken in a plane perpendicular to the Z-axis. The X-axis, Y-axis, and Z-axis are defined also in the other drawings.

The imprint apparatus 1 includes a light irradiation unit 2, a mold holding mechanism 3, a stage 4, an applying unit 5, a heating mechanism (heating unit) 6, an alignment measurement unit 26, a control unit 7, and other components.

The light irradiation unit 2 applies light 9 to the imprint material 14 on the substrate 10 at an imprinting process. The light irradiation unit 2 includes a light source (not shown) and an optical element (not shown) that adjusts the light 9 emitted from the light source to light suitable for imprinting.

The substrate 10 is made of glass, ceramic, metal, a semiconductor, resin, or the like, on which a member made of a material different from the material of the substrate 10 may be formed as needed. Specific examples of the substrate 10 include a silicon wafer, a composite semiconductor wafer, and a quartz glass. An adhesive layer for enhancing adhesion between the imprint material 14 and the substrate 10 may be provided before the imprint material 14 is applied.

The imprint material 14 is applied to the surface of the substrate 10 and is molded using a patterned portion 8a formed on the mold 8. The imprint material 14 is made of a curable composition (also referred to as uncured resin) that is cured on application of curing energy. Examples of the curing energy include an electromagnetic wave, radiation, and heat. Examples of the electromagnetic wave include light, such as infrared rays, visible light, and ultraviolent rays, selected from the range of 10 nm or more and 1 mm or less and electromagnetic radiation, such as X-rays and gamma rays. An example of the radiation is corpuscular radiation, such as an electron beam.

The curable composition is a composition that is cured upon application of light or radiation or by heat. Among them, a light curable composition that is cured by light contains at least a polymerizable compound and a photopolymerization initiator and may further contain non-polymerizable compound or a solvent as needed. The non-polymerizable compound is at least one kind selected from a group of a sensitizer, a hydrogen donator, an internal mold release agent, a surface-active agent, an anti-oxidant, and a polymer component.

The polymerizable compound is a compound that reacts with a polymerizing factor (for example, free radical) generated from the photopolymerization initiator to form a solid composed of a high polymer by a chain reaction (polymerization reaction). In one example, the polymerizable compound is a compound that contains one or more acryloyl group or methacryloyl group, that is, a (meth)acrylic compound. The photopolymerization initiator is a compound that generates a polymerizing factor upon receiving light. An example of the photopolymerization initiator is a radical generator, such as an acylphosphine oxide compound.

The imprint material 14 is applied in a film form onto the substrate 10 by a spin coater or a slit coater. Alternatively, the imprint material 14 may be applied onto the substrate 10 in a droplet form or the form of an island or film formed by connecting a plurality of droplets. The viscosity of the imprint material 14 (the viscosity at 25° C.) is, for example, 1 mPa·s or more and 100 mPa·s or less.

The peripheral shape of the mold 8 is, for example, square, and a surface of the mold 8 facing the substrate 10 includes the patterned portion 8a on which an embossed pattern, such as a circuit pattern, to be transferred is formed in three dimensions. Examples of the material of the mold 8 include glass, quartz, light transmissive resins including a polymethylmethacrylate (PMMA) resin and a polycarbonate resin, a transparent metal evaporated film, a flexible membrane including polydimethylsiloxane, a light curable film, a metal film, and other light transmissive materials. Furthermore, to facilitate deformation, described later, the mold 8 may have a cavity (recess) that is circular in planar shape and having a certain depth on a surface irradiated with the light 9.

The mold holding mechanism 3 includes a mold holding unit 11 that holds the mold 8 and a mold driving mechanism 12 that holds the mold holding unit 11. The mold driving mechanism 12 moves the mold 8 by moving the mold holding unit 11 that holds the mold 8. The mold holding unit 11 can hold the mold 8 by attracting a peripheral area of a light 9 irradiated surface of the mold 8 by a vacuum suction force or an electrostatic force. For example, when the mold holding unit 11 holds the mold 8 using the vacuum suction force, the mold holding unit 11 is connected to a vacuum pump (not shown) installed outside, and mounting and demounting of the mold 8 is switched by ON/OFF of the vacuum pump. The mold holding unit 11 and the mold driving mechanism 12 have an opening area 13 in the center (inside) so that the light 9 emitted from the light irradiation unit 2 travels toward the substrate 10. In the opening area 13, a light transmissive member (not shown) that makes a space enclosed by part of the opening area 13 and the mold 8 an enclosed space is disposed. The light transmissive member is made of a material that transmits the light 9, for example, glass. The pressure in the enclosed space is controlled by a pressure control unit (not shown) including a vacuum pump. The pressure control unit sets the pressure in the space higher than the pressure on the outside when the mold 8 is pressed against the imprint material 14 on the substrate 10. When the pressure in the space rises, the patterned portion 8a bends in a convex shape toward the substrate 10 to allow the patterned portion 8a to come into contact with the imprint material 14 from the center of the patterned portion 8a. This prevents gas (for example, air) from remaining between the patterned portion 8a and the imprint material 14, allowing the imprint material 14 to be filled up to every embossed portion of the patterned portion 8a.

In this embodiment, a process area in which the pattern of the imprint material 14 is formed by pressing and releasing the mold 8 once is a shot area 20 (see FIG. 2). The shot area 20 is a unit area of a ground layer on which a pattern has already been formed and which is partitioned by scribe lines (not shown). A single shot area 20 corresponds to a repetitive pattern formed using a mask by an exposure device, which is used in a back end step. An example of the single shot area is an area of about 26 mm×33 mm in which one or more patterns of a chip size desired by the user is formed.

The mold driving mechanism 12 moves the mold 8 in the Z-axis direction while selectively pressing and releasing the mold 8 to and from the imprint material 14 on the substrate 10. Examples of an actuator that can be employed for the mold driving mechanism 12 include a linear motor and an air cylinder. To address high accuracy positioning of the mold 8, the mold driving mechanism 12 may include a plurality of driving systems including a coarse-movement drive system and a fine-movement drive system. Furthermore, the mold driving mechanism 12 may have a position control function for not only the Z-axis direction but also the X-axis direction, the Y-axis direction, a rotational direction about the x-axis (θx), a rotational direction about the y-axis (θy), and a rotational direction about the z-axis (θz) and a tilt function for correcting the inclination of the mold 8. Although the pressing and releasing operation of the imprint apparatus 1 may be performed by moving the mold 8 in the Z-axis direction using the mold driving mechanism 12, it may be performed by moving the stage 4, described later, in the Z-axis direction, or by moving both of the mold 8 and the stage 4 relative to each other.

The stage 4 holds the substrate 10 and aligns the mold 8 and the imprint material 14 in pressing of the mold 8 and the imprint material 14 on the substrate 10. The stage 4 includes a substrate holding unit 16 that holds the substrate 10 by a suction force and a stage driving mechanism 17 that mechanically holds the substrate holding unit 16 and can move the substrate holding unit 16 in the axial directions. Examples of an actuator that can be employed for the stage driving mechanism 17 include a linear motor and a planar motor. The stage driving mechanism 17 may also be composed of a plurality of driving systems including a rough-movement drive system and a fine-movement drive system for the X-axis and Y-axis directions. Furthermore, the stage driving mechanism 17 may have a drive system for position adjustment in the Z-axis direction, a position adjusting function in the θ-direction of the substrate 10, and a tilt function for correcting the inclination of the substrate 10. The stage 4 further includes a plurality of reference mirrors 18 on the sides, corresponding to the X-, Y-, Z-, θx-, θy-, and θz-directions. The imprint apparatus 1 includes a plurality of laser interferometers 19 that apply beams to the plurality of reference mirrors 18 in correspondence with the individual reference mirrors 18. The position of the stage 4 is measured by the plurality of laser interferometers 19. The laser interferometers 19 measure the position of the stage 4 in real time. The control unit 7, described later, executes positioning control of the substrate 10 on the stage 4 on the basis of the measured values at that time.

The applying unit 5 is disposed in the vicinity of the mold holding mechanism 3 and applies the uncured imprint material 14 onto the substrate 10. The amount of the imprint material 14 discharged from a discharge nozzle 5a of the applying unit 5 is determined as appropriate depending on a desired thickness of the imprint material 14 to be formed on the substrate 10 and the density of a pattern to be formed.

For the imprinting process, the alignment measurement unit 26 acquires the shape of the patterned portion 8a of the mold 8 and the shape of the shot area 20 on the substrate 10. The alignment measurement unit 26 may be configured to acquire the shape of the patterned portion 8a and the shape of the shot area 20 also during the imprinting process.

The control unit 7 controls the operations of the components of the imprint apparatus 1. The control unit 7 is constituted by, for example, a computer, is connected to the components of the imprint apparatus 1 via a line, and executes control of the components according to a program or the like. The control unit 7 may be configured in a casing common to the other parts of the imprint apparatus 1 or may be configured in a casing separate from the other parts of the imprint apparatus 1. The control unit 7 may be constituted by a plurality of computers and may be included in the components to be controlled.

The imprint apparatus 1 includes a base platen 27 on which the stage 4 is placed, a bridge platen 28 that fixes the mold holding mechanism 3, and support columns 30 extended from the base platen 27 to support the bridge platen 28 via vibration isolators 29. The vibration isolators 29 eliminate vibration transmitted from the floor surface to the bridge platen 28. The imprint apparatus 1 can further include a mold conveying mechanism that conveys the mold 8 from the outside of the imprint apparatus 1 to the mold holding mechanism 3 and a substrate conveying mechanism that conveys the substrate 10 from the outside of the imprint apparatus 1 to the stage 4, although both are not shown.

Referring to FIG. 2, the heating mechanism 6 that heats the mold 8 and the substrate 10 and a mold-shape correcting mechanism will be described. FIG. 2 is a diagram illustrating the configuration and disposition of the heating mechanism 6 and so on. In FIG. 2, the same components as those in FIG. 1 are given the same reference signs, and descriptions thereof will be omitted.

The heating mechanism 6 heats the shot area 20 on the substrate 10 and the patterned portion 8a of the mold 8. The heating mechanism 6 includes a heating light source 22 (a light source) that applies irradiation light 21 for heating the shot area 20 and the patterned portion 8a. The heating mechanism 6 further includes a light adjustor 23 (an adjusting unit) that adjusts the irradiation dose of the irradiation light 21 and a reflector 25 that defines the optical path so that the adjusted light 24 travels toward the surface of the substrate 10. The irradiation light 21 emitted from the heating light source 22 may be light having a wavelength out of the wavelength band of light to which the imprint material 14 is exposed (cured). For example, when the imprint material 14 is a photocurable resin that is cured by ultraviolent rays in a wavelength band of 200 to 400 nm, the irradiation light 21 can be light in a wavelength band of 400 to 1,200 nm. For example, when the material of the mold 8 is quartz, in particular, visible light in a wavelength band of 400 to 750 nm may be used. When the adjusted light 24 is applied onto the substrate 10 via the mold 8, visible light is hardly absorbed in the mold 8 because the light absorption rate of the mold 8 for visible light is lower than the light absorption rate of the substrate 10. The light absorption rate is a ratio at which light applied to a certain substance is absorbed. When the light absorption rate is high, the amount of heat generated by light absorption is large.

The light adjustor 23 allows light having a specific wavelength in the irradiation light 21 to be applied toward the surface of the substrate 10 via an optical filter (not shown) in order to form a desired dose distribution in at least a planer area of the shot area 20. An example of the light adjustor 23 is a liquid crystal device including a plurality of liquid crystal devices as light modulation elements on a light transmitting surface and capable of changing the dose distribution by individually controlling voltages to be applied to the plurality of liquid crystal devices. Another example of the light adjustor 23 is a digital micromirror device (DMD) including a plurality of mirror elements as light modulation elements on a light reflecting surface and capable of changing the dose distribution by individually adjusting the plane directions of the mirror elements. The DMD controls the irradiation time of light reflected by the mirror elements and applied onto the substrate 10 by controlling the time during which the light reflecting surface of each mirror element is inclined in a predetermined direction. As a result, the amounts of heat generated in minute regions on the substrate 10 corresponding to the individual mirror elements are adjusted, forming a desired temperature distribution on the shot area 20. Alternatively, the heating light source 22 may include a plurality of light sources from which light to be emitted can be individually adjusted, and the light adjustor 23 may employ a method of changing the dose distribution by individually adjusting the light to be emitted. Whichever method is adopted, the light adjustor 23 can apply the irradiation light 21 onto the surface of the substrate 10 with a uniform dose distribution or an uneven dose distribution.

The heating light source 22 and the light adjustor 23 may be disposed in the imprint apparatus 1 so as not to obstruct the optical path of the light 9 emitted from the light irradiation unit 2 when curing the imprint material 14. In this embodiment, the heating light source 22 and the light adjustor 23 are disposed at positions above the opening area 13 (near the light irradiation unit 2), at which the adjusted light 24 is radiated from a side in the X-axis direction. In this case, the adjusted light 24 enters a space connected to the opening area 13, is then reflected by the reflector 25, and passes through the mold 8 onto the shot area 20 on the substrate 10. Meanwhile, the light 9 radiated from the light irradiation unit 2 passes through the reflector 25 onto the substrate 10. The reflector 25 may be a dichroic mirror or the like that can switch between transmission and reflection depending on the wavelength of the light.

The mold-shape correcting mechanism (a mold-shape correcting unit) 201 is a mechanism for correcting the shape of the patterned portion 8a by applying an external force to the periphery of the mold 8. The mold-shape correcting mechanism 201 is mounted on the mold holding unit 11 and is capable of correcting the shape of the patterned portion 8a by pressurizing the mold 8 from the peripheral direction using a cylinder that operates with fluid, such as air or oil, or a piezoelectric element.

An imprinting process in the related art will be described hereinbelow. In the imprint apparatus of the related art, the same components as those of the imprint apparatus 1 in FIG. 1 are denoted by the same reference signs, and descriptions thereof will be omitted. As described above, the shot area 20 on the substrate 10 can be enlarged or contracted before being carried into the imprint apparatus 1, so that the shape (or the size) can be changed in the directions of two axes intersecting at right angles in an X-Y plane. Examples of the deformation components of the shot area 20 include magnification, a parallelogram or trapezoidal linear component, and arched and reel-shaped or barrel-shaped higher-order components, and which are combined to deform the shot area 20. When pressing the mold 8 and the imprint material 14 on the substrate 10 together, the imprint apparatus 1 corrects the shape of the shot area 20 and the shape of the patterned portion 8a so that the shapes can be aligned. The imprint apparatus 1 achieves the alignment by thermally deforming the shot area 20 on the substrate 10 on the basis of the amount of correction calculated from the result of measurement by the alignment measurement unit 26 and further by elastically deforming the patterned portion 8a.

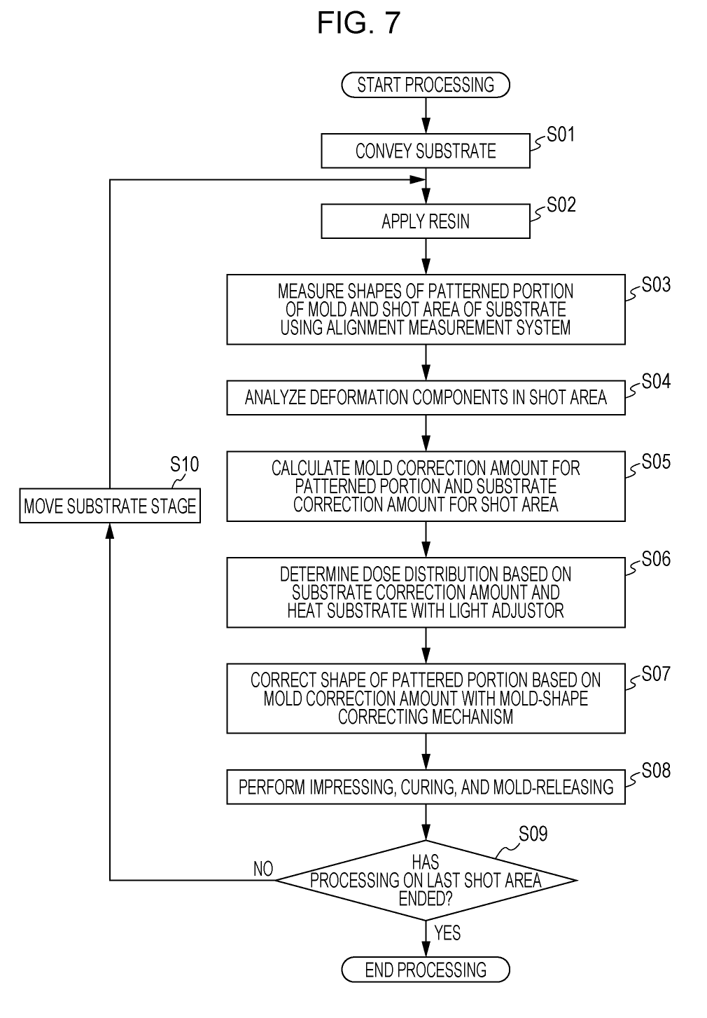

FIG. 7 is a flowchart for the imprinting process of the related art. First, the control unit 7 causes a substrate conveying mechanism (not shown) to carry in the substrate 10 and the substrate holding unit 16 to hold the substrate 10 on the stage 4 (S01). Next, the control unit 7 drives the stage driving mechanism 17 to move the stage 4 so that the shot area 20 on the substrate 10 is positioned at a position of application performed by the applying unit 5. Then, the control unit 7 causes the applying unit 5 to apply the imprint material 14 onto the shot area 20 (S02).

Next, the control unit 7 drives the stage driving mechanism 17 to move the stage 4 so that the shot area 20 on which the imprint material 14 is applied is positioned directly below the patterned portion 8a. The control unit 7 then causes the alignment measurement unit 26 (a shape acquisition unit) to measure the shape of the patterned portion 8a and the shape of the shot area 20 (S03). The alignment measurement unit 26 measures alignment marks disposed at the four corners of the patterned portion 8a and the shot area 20 to determine the shape of the patterned portion 8a and the shape of the shot area 20 from the positions of the alignment marks in the x-y direction. The alignment marks may not necessarily be disposed at the four corners of the patterned portion 8a and the shot area 20. For example, a plurality of alignment marks may be disposed at appropriate positions in the vicinity of the outer peripheries of the patterned portion 8a and the shot area 20. The shape of the patterned portion 8a and the shape of the shot area 20 may be measured before the imprinting process, and the measurement results may be used.

The alignment measurement unit 26 may determine the difference between the shape of the patterned portion 8a and the shape of the shot area 20 by measuring the alignment marks disposed at the patterned portion 8a and the shot area 20 at the same time. In this case, the alignment measurement unit 26 measures the alignment marks immediately before the mold 8 and the imprint material 14 on the substrate 10 are pressed together or after they are pressed and before they are released.

Next, the control unit 7 analyzes deformation components contained in the shot area 20 from the measurement results (S04). The control unit 7 causes a calculation unit (not shown) in the control unit 7 to calculate a mold correction amount for the patterned portion 8a and a substrate correction amount for the shot area 20 on the substrate 10 from the result of analysis (S05).

Next, the control unit 7 determines a dose distribution on the basis of the substrate correction amount and causes the light adjustor 23 to form the adjusted light 24. The adjusted light 24 heats the substrate 10 to thermally deform the shot area 20, so that the shape of the shot area 20 is corrected (S06). For the dose distribution, dose distribution patterns corresponding to various deformation components and correction amounts may be prepared in advance, from which a dose distribution necessary for correcting the shot area 20 may be derived. The control unit 7 controls the operations of the heating light source 22 and the light adjustor 23 using the determined dose distribution as an indicator. At that time, a temperature distribution is formed in and out of the planer area of the shot area 20 upon receiving the light (the adjusted light 24) having the dose distribution.

Next, the control unit 7 causes the mold-shape correcting mechanism 201 to apply an external force to the mold 8 on the basis of the mold correction amount to correct the shape of the patterned portion 8a (S07).

Next, the control unit 7 drives the mold driving mechanism 12 to press the mold 8 against the imprint material 14 on the substrate 10 (impressing process). This causes the imprint material 14 to fill the embossed portion of the patterned portion 8a. In that state, the control unit 7 causes the light irradiation unit 2 to emit the light 9 from above the mold 8 to cure the imprint material 14 using the light 9 transmitted through the mold 8 (curing process). After the imprint material 14 is cured, the control unit 7 drives the mold driving mechanism 12 to release the mold 8 from the imprint material 14 (mold-releasing process). This forms a pattern (layer) of the imprint material 14 on the shot area 20 in a three-dimensional form corresponding to the embossed portion of the patterned portion 8a (S08).

Next, the control unit 7 determines whether an imprinting process on the last shot area 20 of the plurality of shot areas 20 formed on the substrate 10 is completed (S09 YES). If at S09 the control unit 7 determines that the imprinting process has not been completed (S09 NO), then the control unit 7 drives the stage driving mechanism 17 to move the stage 4 (S10). The control unit 7 then returns to the step S02 to perform an imprinting process on the next shot area. If at S09 the control unit 7 determines that the imprinting process has been completed, then the control unit 7 terminates the imprinting process on the substrate 10. By executing the imprinting process, a plurality of times while changing the shot area 20 by driving the stage 4, a plurality of patterns of the imprint material 14 can be formed on the single substrate 10.

In the impressing process at S08, if the mold 8 of which temperature is a similar temperature to the temperature in the imprint apparatus 1 is brought into contact with the shot area 20 that is heated by the heating mechanism 6 to form a temperature distribution, the heat transfers between the substrate 10 and the mold 8 to change the temperature distribution formed on the substrate 10. This changes the shape of the shot area 20 to decrease the accuracy of alignment of the patterned portion 8a and the shot area 20.

Therefore, this embodiment is configured to prevent the heat transfer between the mold 8 and the substrate 10 by heating the mold 8 so that the difference between the temperature on the substrate 10 and the temperature of the mold 8 is small.

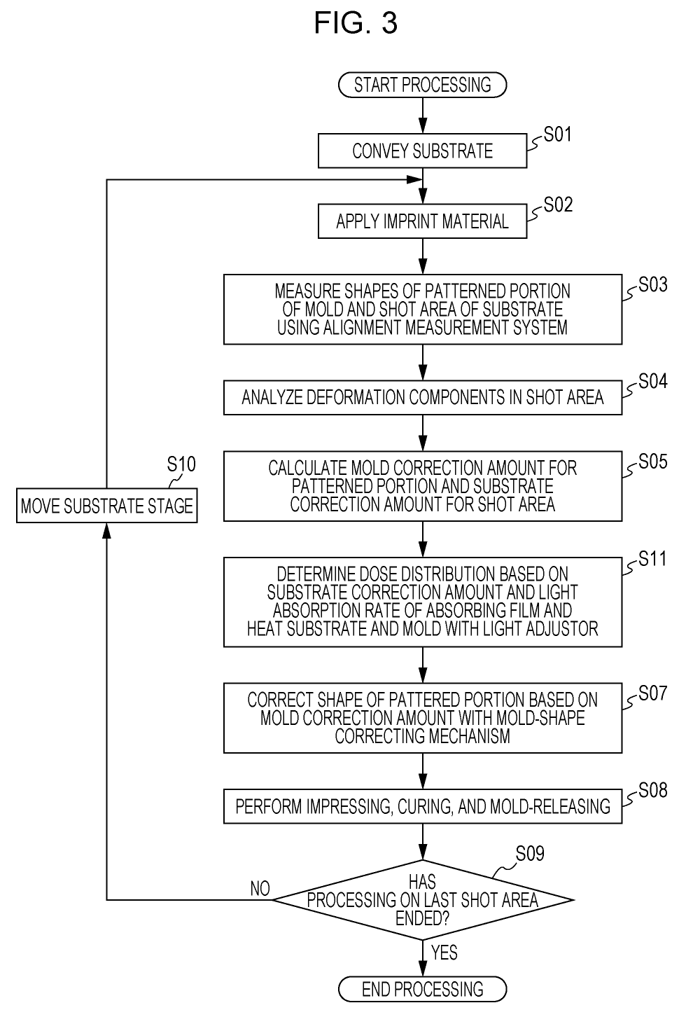

The imprinting process of this embodiment will be described with reference to the flowchart shown in FIG. 3. First, the process from S01 to S05 is the same as the process from S01 to S05 in FIG. 7, and a description thereof will be omitted. At S11, a dose distribution is determined by the control unit 7 from the substrate correction amount, and the adjusted light 24 is formed by the light adjustor 23. A temperature distribution is formed on the substrate 10 by the adjusted light 24, and the shot area 20 is thermally deformed to correct the shape of the shot area 20. Furthermore, the mold 8 of this embodiment is configured to absorb part of the adjusted light 24 to form a temperature distribution on the patterned portion 8a of the mold 8 while the adjusted light 24 generates a temperature distribution on the substrate 10.

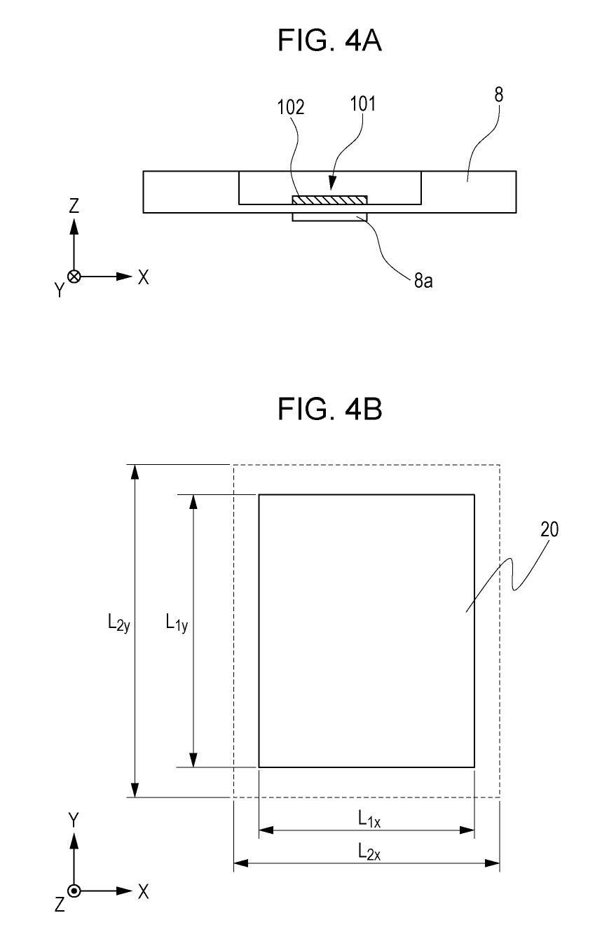

FIGS. 4A and 4B are diagrams illustrating the configuration of the mold 8 according to this embodiment and the shot area 20 on the substrate 10. A configuration for forming a temperature distribution on the patterned portion 8a of the mold 8 will be described. As illustrated in FIG. 4A, the mold 8 of this embodiment has an absorbing portion (a light absorbing portion) 101 that absorbs the energy of part of the adjusted light 24 on a surface opposite to the surface on which the patterned portion 8a is formed. The absorbing portion 101 has the characteristics of absorbing light of a wavelength in a certain range (part of the light) and transmitting light of a wavelength in the other range (the other part of the light) and generates heat due to the energy of the absorbed light. Therefore, a temperature distribution is formed by the adjusted light 24 also on the patterned portion 8a of the mold 8, so that the heat transfer between the substrate 10 and the mold 8 can be reduced. The absorbing portion 101 may be an absorbing film 102 that absorbs light. An example of the absorbing film 102 is an absorption-type neutral density (ND) filter that absorbs light of a specific wavelength in the range of 400 to 1,200 nm, which is the wavelength band of the irradiation light 21. An example of the ND filter is a metal film containing chromium or a nickel alloy. Such a ND filter can be changed in light absorption rate by changing the film thickness. The light absorption rate of the absorbing film 102 is determined so that, when the adjusted light 24 is applied, the temperature distribution formed on the shot area 20 and the temperature distribution formed on the patterned portion 8a has a certain temperature difference or less. Actually, the light absorption rate of the absorbing film 102 is determined on the basis of the physical property of the mold 8 and the temperature of the ambient environment of the mold 8.

For example, suppose that the temperature distribution of the patterned portion 8a of the mold 8 and the temperature distribution of the substrate 10 become equal by equalizing the amounts of heat generated in the mold 8 and the substrate 10. Assume that the substrate 10 has a light absorption rate of 85% for light with a wavelength of 450 nm and the mold 8 has an absorbing film 102 having a light absorption rate of A[%]for light with a wavelength of 450 nm. In this case, when light with a wavelength of 450 nm and a radiation dose of 2.0 [W] is applied, the relationship between the amount of heat h₁ [W] generated in the mold 8 and the amount of heat h₂ [W] generated in the substrate 10 is as follows:

h₁=A×2.0 (1)

h₂=(2.0−h₁)×0.85 (2)

h₁=h₂ (3)

Accordingly, the light absorption rate A of the absorbing film 102 can be determined to be about 0.46[%] from Eqs. (1) to (3). In these calculations, loss due to surface reflection is not considered.

The control unit 7 adjusts the amount of irradiation light 21 emitted from the heating light source 22 and the dose distribution of the adjusted light 24 using the light adjustor 23. At that time, the radiation dose and the dose distribution are adjusted so that a temperature distribution necessary for correcting the shape of the shot area 20 and the temperature difference between the temperature distribution formed on the shot area 20 and the temperature distribution formed on the patterned portion 8ais smaller than a threshold value. The threshold value T can be obtained using Eq. (4), where L₁ₓ is the length of the shot area 20 in the X-direction, L₂ₓ is the length of the shot area 20 in the X-direction after being changed in shape, and E is the coefficient of linear expansion of the substrate 10, as illustrated FIG. 4B.

T=(L₂ₓ−L₁ₓ)/(E×L₁ₓ)=RC/E (4)

RC is the rate of change in the length of the shot area 20 in the X-direction. For example, assume that the length L₁ₓ of the side of the shot area 20 in the X-direction is 26 mm and that the difference between the length L₂ₓ of the shot area 20 in the X-direction after the shape changes and the length L₁ₓ before the shape changes is 4.0 nm as a permissible value for alignment accuracy, RC is about 1.5×10⁻⁷. Assume that the coefficient of linear expansion, E, of the substrate 10 is 2.4 ppm. If the values are substituted in Eq. (4), the threshold value T is about 0.064° C. Thus, the dose distribution of the adjusted light 24 is controlled in consideration of the light absorption rate of the absorbing film 102 so that the temperature difference between the temperature distribution on the shot area 20 and the temperature distribution on the patterned portion 8a is smaller than the threshold value. Furthermore, the threshold value can be obtained also for the Y-direction as for the X-direction by using the length L_{1y} of the shot area 20 in the Y-direction and the length L_{2y} after the shape changes. In this case, a smaller threshold value of the threshold values for the X-direction and the Y-direction may be employed. Although the above embodiment has been described for a case where the shot area 20 changes in the direction of expansion, the threshold value can be obtained by the same method also in a case where the shot area 20 changes in the direction of contraction.

In this manner, the amount of deformation of the shot area 20 caused by heat transfer from the substrate 10 to the mold 8 can be kept within a certain range, so that a decrease in the accuracy of alignment of the patterned portion 8a and the shot area 20 can be reduced or eliminated.

Alternatively, instead of the absorbing film 102, a material having characteristics of absorbing light with a wavelength in a certain range and transmitting light with a wavelength in the other range may be mixed in the material of the mold 8 to form the absorbing portion 101. In one example, fine particles of cadmium sulfide may be mixed. In this case, the light absorption rate can be adjusted by changing the mixing ratio of the material. The absorbing portion 101 may include the absorbing film 102 and the mixed material.

Returning to FIG. 3, the subsequent imprinting process will be described. At S07 in FIG. 3, the control unit 7 causes the mold-shape correcting mechanism 201 to correct the shape of the patterned portion 8a, with a temperature distribution formed on the patterned portion 8a (S07). By forming a temperature distribution on the patterned portion 8a, the patterned portion 8a is deformed by thermal expansion. In this embodiment, if the material of the mold 8 is quartz, the coefficient of linear expansion is about 0.5 ppm. If the material of the substrate 10 is monocrystalline silicon, the coefficient of linear expansion is about 2.4 ppm. For example, when the length of the shot area 20 is corrected by 12 nm by forming a temperature distribution thereon, the length of the patterned portion 8a changes by about 2.5 nm. Thus, the shape change of the patterned portion 8a due to heat is smaller than the shape change of the shot area 20 of the substrate 10, and the shape of the shot area 20 of the substrate 10 can be corrected such that shape difference between the patterned portion 8a and shot area 20 can be reduced. Furthermore, even if the patterned portion 8a has a temperature distribution due to heat, so that the shape of the patterned portion 8a changes due to thermal expansion, the shape change can be corrected using the mold-shape correcting mechanism 201. The shape of the patterned portion 8a and the shape of the shot area 20 are measured with the alignment measurement unit 26. Then, the shape of the patterned portion 8a is corrected by elastic deformation by applying an external force to the mold 8 on the basis of the measurement results using the mold-shape correcting mechanism 201 so that the difference in shape between the patterned portion 8a and the shot area 20 becomes small.

Next, as at S08 in FIG. 7, the control unit 7 performs the impressing process, the curing process, and the mold-releasing process (S08). In the impressing process, the patterned portion 8a on which a temperature distribution whose difference in temperature from the temperature distribution formed on the shot area 20 is smaller than a predetermined threshold value is pressed against the shot area 2. This can reduce heat transfer between the substrate 10 and the mold 8. This reduces or eliminates a change in the shape of the shot area 20, thereby preventing a decrease in alignment accuracy of the patterned portion 8a and the shot area 20. The adjusted light 24 may be continuously applied during the impressing process (S08) in the flowchart illustrated in FIG. 3 in order to keep the generated temperature distributions of the shot area 20 on the substrate 10 and the patterned portion 8a of the mold 8. The adjusted light 24 may be continuously applied until the curing process and the mold-releasing process (S08). The application of the adjusted light 24 may be started after the start of the impressing process (S08). Since steps S09 and S10 in FIG. 3 are the same as steps S09 and S10 in FIG. 7, descriptions thereof will be omitted.

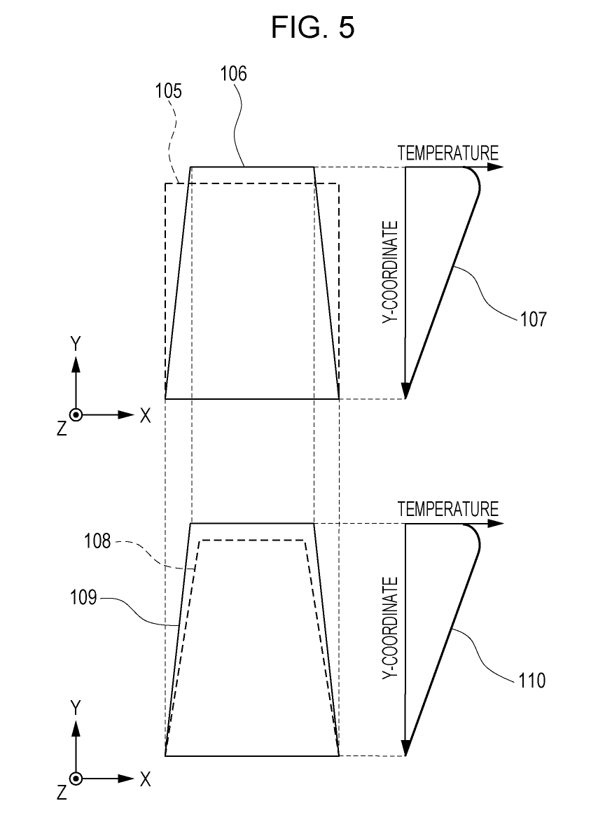

FIG. 5 is a diagram illustrating correction of the shapes of the patterned portion 8a of the mold 8 and the shot area 20 of the substrate 10 and their temperature distributions. Here, a case where deformation containing only a trapezoidal component occurs in the shot area 20 will be described as an example. The adjusted light 24 is applied to a pre-correction shape 108 of the shot area 20 to form a temperature distribution 110. In this case, the deformation of the trapezoidal component in the shot area 20 is only in the X-direction, and therefore the temperature distribution 110 is given an inclination only in the Y-direction. Due to the temperature distribution 110, the pre-correction shape 108 is thermally deformed into a corrected shape 109 of the shot area 20. Meanwhile, a temperature distribution 107 whose temperature difference from the temperature distribution 110 is smaller than a threshold value is formed on the patterned portion 8a, and a pre-correction shape 105 of the patterned portion 8a is deformed into a corrected shape 106 by applying an external force to the mold 8 with the mold-shape correcting mechanism 201. After the correction into the corrected shape 109 of the shot area 20 and the corrected shape 106 of the patterned portion 8a is completed, the mold 8 and the substrate 10 are brought into contact with each other via the imprint material 14. At that time, heat transfer between the substrate 10 and the mold 8 is reduced to make the temperature difference between the temperature distribution of the substrate 10 and the temperature distribution of the patterned portion 8a smaller than the threshold value, so that the corrected shape 109 and the corrected shape 106 are kept.

Thus, with the imprint apparatus according to this embodiment, a decrease in alignment accuracy can be reduced or eliminated.

### Second Embodiment

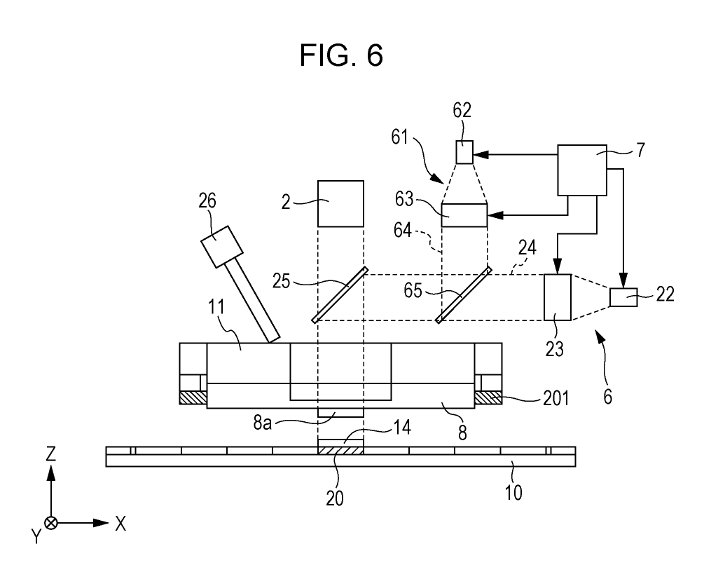

An imprint apparatus according to a second embodiment will be described. FIG. 6 is a diagram illustrating the configuration and disposition of a mold heating mechanism. A feature of the imprint apparatus of this embodiment is that it includes a mold heating mechanism (a mold heating unit) 61 including an infrared radiation source 62 illustrated in FIG. 6. The mold heating mechanism 61 heats the mold 8 by irradiating the mold 8 with light. The mold heating mechanism 61 includes the infrared radiation source 62 that emits infrared rays for heating the mold 8, a mold light adjustor (an adjusting unit) 63 that adjusts the dose distribution of the emitted infrared rays, and a reflector 65 that defines the optical path of the adjusted infrared rays 64 so that the infrared rays 64 are directed toward the surface of the mold 8. The infrared rays may be light with a wavelength band of, for example, 750 nm to 1,000 μm. When the mold 8 is made of quartz, the infrared rays applied to the mold 8 are absorbed in the mold 8. When the substrate 10 is made of monocrystalline silicon, the infrared absorption rate of the substrate 10 is smaller than the infrared absorption rate of the mold 8, and is therefore hardly absorbed in the substrate 10. The mold light adjustor 63 includes a light modulation element capable of changing the dose distribution, as the light adjustor 23 does.

A temperature distribution formed on the shot area 20 on the substrate 10 is formed such that the heating light source 22 and the light adjustor 23 of the heating mechanism (substrate heating unit) 6 are controlled by the control unit 7 so that the adjusted light 24 is applied to the substrate 10, as in the first embodiment. The control unit 7 controls the dose distribution of the adjusted infrared rays 64 with the mold light adjustor 63 so that a temperature distribution whose temperature difference from the temperature distribution formed on the shot area 20 is smaller than a threshold value is formed on the patterned portion 8a. This allows the amount of deformation of the shot area 20 that occurs due to heat transfer from the substrate 10 to the mold 8 to be within a certain range, thereby reducing a decrease in alignment accuracy of the patterned portion 8a and the shot area 20.

The adjusted light 24 and the adjusted infrared rays 64 are applied to the reflector 65. The reflector 65 may be a dichroic mirror having characteristics of, for example, reflecting light with a wavelength in the infrared region and transmitting light with a wavelength in a visible region shorter than that of the infrared region. The adjusted light 24 and the adjusted infrared rays 64 are guided to the reflector 25 by the reflector 65. The reflector 25 may be a dichroic mirror having characteristics of, for example, reflecting light with a wavelength in the infrared region and transmitting light with a wavelength in the ultraviolet region shorter than that of the visible region. With the reflector 25, the adjusted infrared rays 64 are applied to the mold 8, and the adjusted light 24 passes through the mold 8 onto the substrate 10.

At S11 in the flowchart for the imprinting process illustrated in FIG. 3, when forming a temperature distribution on the substrate 10, the control unit 7 forms a temperature distribution also on the patterned portion 8a of the mold 8 using the above configuration. The other of the imprinting process is basically the same as that described in the first embodiment.

Depending on the infrared absorption rate and the geometry, such as the thickness, of the mold 8 made of quartz or the like, not all of the energy of the adjusted infrared rays 64 applied to the mold 8 can be absorbed in the mold 8, and part thereof can be applied to the substrate 10. However, the influence on the temperature distribution formed on the shot area 20 of the substrate 10 is low because the material of the substrate 10 is monocrystalline silicon, and therefore the infrared absorption rate of the substrate 10 is low.

Alternatively, a light adjustor 23 that can deal with light with wavelengths in visible range and infrared range may be used, and the mold light adjustor 63 may not be used.

The imprint apparatus of this embodiment may have a configuration including a temperature measuring unit (not shown). The temperature measuring unit measures a temperature distribution formed on the shot area 20 of the substrate 10 and a temperature distribution formed on the patterned portion 8a of the mold 8. The control unit 7 controls the dose distribution of the adjusted infrared rays 64 with the mold light adjustor 63 on the basis of the measurement results of the temperature distributions so that a temperature distribution whose temperature difference from the temperature distribution of the shot area 20 is smaller than a threshold value is formed on the patterned portion 8a. Examples of the temperature measuring unit include non-contact thermometers, such as a radiation thermometer and an infrared thermometer.

Thus, with the imprint apparatus of this embodiment, a decrease in alignment accuracy can be reduced or eliminated.

### Method for Producing Article

A pattern of a cured product formed using an imprint apparatus can be permanently used for at least part of various articles or temporarily used for producing various articles. Examples of the articles include electric circuit elements, optical elements, MEMS, recording elements, sensors, and molds. Examples of the electric circuit elements include volatile or non-volatile semiconductor memories, such as a dynamic random access memory (DRAM), a static random access memory (SRAM), a flash memory, and a magnetoresistive random access memory (MRAM), and semiconductor devices, such as a large scale integration (LSI), a charge coupled device (CCD), an image sensor, and a field-programmable gate array (FPGA). Example of the optical elements include a micro lens, a light guide, a waveguide, an antireflection film, a diffraction grating, a polarizing element, a color filter, a light-emitting device, a display, and a solar battery. Examples of the MEMS include a digital mirror device (DMD), a microchannel, and an electromechanical conversion element. Examples of the recording elements include optical discs, such as a compact disc (CD) and a digital versatile disc (DVD), magnetic disks, magnetooptical disks, and magnetic heads. Examples of the sensors include a magnetic sensor, an optical sensor, and a gyroscope. An example of the mold is an imprinting mold.

A pattern of a cured object is used as it is as at least part of the components of the article or temporarily used as a resist mask. The resist mask is removed after etching or ion implantation is performed during a substrate processing process.

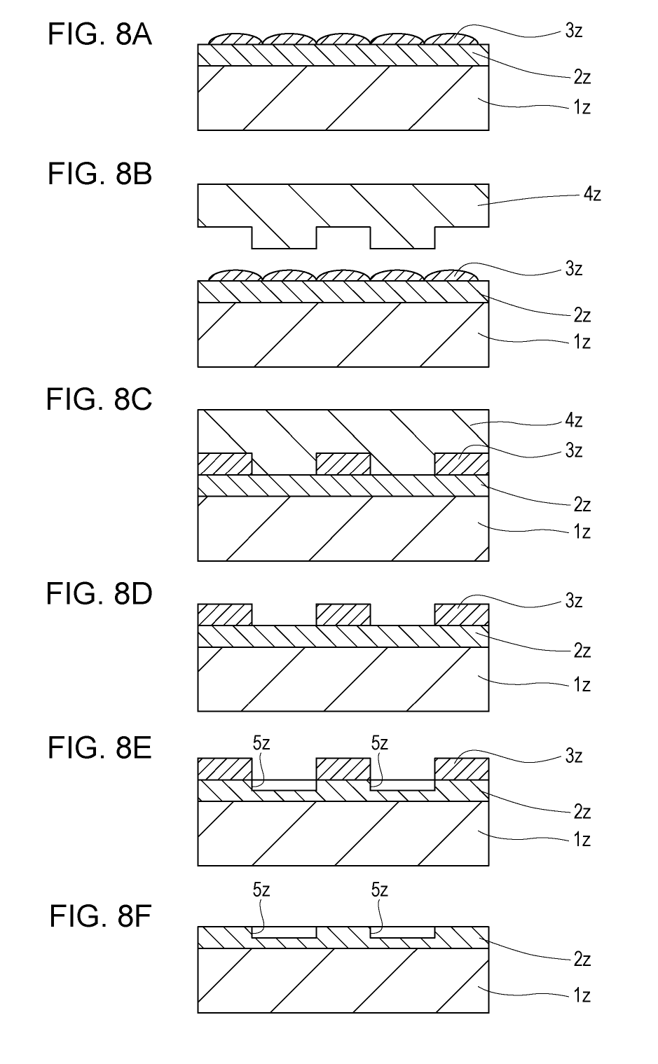

Next, a specific method for producing an article will be described. As illustrated in FIG. 8A, a substrate 1z, such as a silicon wafer, on the surface of which a workpiece 2z, such as an insulator, is provided, is prepared. Subsequently, an imprint material 3z is applied onto the surface of the workpiece 2z by an ink-jet method or the like. FIG. 8A illustrates a state in which the imprint material 3z in the form of a plurality of droplets is applied on the substrate 1z.

As illustrated in FIG. 8B, an imprinting mold 4z is opposed to the imprint material 3z on the substrate 1z, with a surface on which an embossed pattern is formed opposed to the imprint material 3z. As illustrated in FIG. 8C, the substrate 1z on which the imprint material 3z is applied and the mold 4z are brought into contact with each other, and pressure is applied thereto. The imprint material 3z fills the gap between the mold 4z and the workpiece 2z. When light is applied as curing energy through the mold 4z in that state, the imprint material 3z is cured.

As illustrated in FIG. 8D, when the mold 4z and the substrate 1z are separated from each other after the imprint material 3z is cured, a pattern of the cured imprint material 3z is formed on the substrate 1z. The pattern of the cured imprint material 3z has a shape in which the recesses of the mold 4z correspond to the protrusions of the cured product, and the protrusions of the mold 4z correspond to the recesses of the cured product. In other words, the embossed pattern of the mold 4z is transferred to the imprint material 3z.

As illustrated in FIG. 8E, when etching is performed using the pattern of the cured product as an etching resistant mask, portions of the surface of the workpiece 2z where no cured product is present or thinly left is removed to form grooves 5z. As illustrated in FIG. 8F, when the pattern of the cured product is removed, an article in which the grooves 5z are formed on the surface of the workpiece 2z can be obtained. In this case, the pattern of the cured product is removed. Alternatively, the pattern may not be removed after the processing and may be used as an interlayer dielectric film included in a semiconductor device or the like, that is, a component of the article.

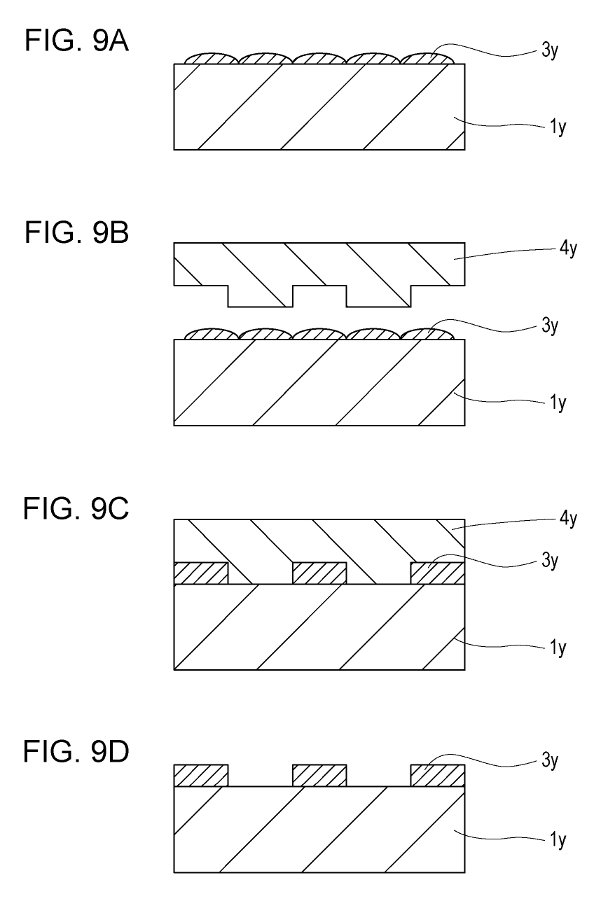

Next, another method for producing an article will be described. As illustrated in FIG. 9A, a substrate 1y made of quartz glass or the like is prepared, and an imprint material 3y is applied onto the surface of the substrate 1y by an ink-jet method or the like. A layer of another material, such as metal or a metal compound, may be provided on the surface of the substrate 1y as needed.

As illustrated in FIG. 9B, an imprinting mold 4y is opposed to the imprint material 3y on the substrate 1y, with a surface on which an embossed pattern is formed opposed to the imprint material 3y. As illustrated in FIG. 9C, the substrate 1y on which the imprint material 3y is applied and the mold 4y are brought into contact with each other, and pressure is applied thereto. The imprint material 3y fills the gap between the mold 4y and the substrate 1y. When light is applied through the mold 4y in that state, the imprint material 3y is cured.

As illustrated in FIG. 9D, when the mold 4y and the substrate 1y are separated from each other after the imprint material 3y is cured, a pattern of the cured imprint material 3y is formed on the substrate 1y. Thus, an article having the pattern of the cured product as a component is acquired. When the substrate 1y is etched using the pattern of the cured product as a mask in the state of FIG. 9D, an article in which the recesses and the protrusions are reversed from those of the mold 4y, such as an imprinting mold, can be acquired.

Having described embodiments of the present disclosure, it is to be understood that the present disclosure is not limited to the embodiments and that various modifications and changes can be made within the scope of the spirit thereof. The imprint apparatuses according to the first and second embodiments may be provided not only solely but also in combination of the first and second embodiments. The process area in which the pattern of the imprint material 14 is formed by a single contact and releasing operation on the mold 8 and the imprint material 14 may include a plurality of shot areas 20.

According to the embodiments of the present disclosure, an imprint apparatus, a method of imprinting, a method for producing an article, and a mold in which a decrease in alignment accuracy is reduced or eliminated can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-075989 filed Apr. 5, 2016, which is hereby incorporated by reference herein in its entirety.

What is claimed is:

1. An imprint apparatus for forming a pattern of an imprint material on a process area of a substrate by using a mold including a patterned portion, the apparatus comprising:
a heating unit configured to heat the mold and the substrate,
wherein the heating unit heats the substrate such that a difference in shape between the process area and the patterned portion is reduced, and
wherein the heating unit heats the mold such that a difference in temperature between the mold and the heated substrate is reduced.

2. An imprint apparatus for forming a pattern of an imprint material on a process area of a substrate by using a mold including a patterned portion, the apparatus comprising:
a heating unit configured to heat the mold and the substrate by applying light to the mold and the substrate,
wherein the heating unit causes a light absorbing portion to absorb part of the light and applies light that has passed through the light absorbing portion and the mold to the substrate, such that a difference in shape between the process area and the patterned portion is reduced and a difference in temperature between the patterned portion and the process area is smaller than a threshold value.

3. The imprint apparatus according to claim 2,
wherein the heating unit comprises an adjusting unit configured to adjust irradiation dose of the light,
wherein the adjusting unit comprises a light modulation element and adjusts an irradiation dose distribution of the light using the light modulation element such that a difference in shape between the process area and the patterned portion is reduced, and
wherein the heating unit causes a difference in temperature distribution between the patterned portion and the process area to be smaller than a threshold value by applying light whose dose distribution is adjusted by the adjusting unit to the light absorbing portion of the mold and by applying the light that has passed through the light absorbing portion and the mold to the substrate.

4. The imprint apparatus according to claim 2,
wherein the heating unit comprises an adjusting unit configured to adjust irradiation dose of the light,
wherein the adjusting unit comprises a plurality of light sources whose radiation can be adjusted, the adjusting unit adjusts an irradiation dose distribution of light from the plurality of light sources such that a difference in shape between the process area and the patterned portion is reduced, and
wherein the heating unit makes a difference in temperature distribution between the patterned portion and the process area smaller than a threshold value by applying light whose dose distribution is adjusted by the adjusting unit to the light absorbing portion of the mold and by applying the light that has passed through the light absorbing portion and the mold to the substrate.

5. An imprint apparatus for forming a pattern of an imprint material on a process area of a substrate by using a mold including a patterned portion, the apparatus comprising:
a substrate heating unit configured to heat the substrate; and
a mold heating unit configured to heat the mold,
wherein the substrate heating unit heats the substrate such that a difference in shape between the process area and the patterned portion is reduced, and
wherein the mold heating unit heats the mold such that a difference in temperature between the mold and the substrate is smaller than a threshold value.

6. An imprint apparatus for forming a pattern of an imprint material on a process area of a substrate by using a mold including a patterned portion, the apparatus comprising:
a substrate heating unit configured to heat the substrate by applying first light to the substrate, the first light having a light absorption rate for the substrate higher than a light absorption rate for the mold; and
a mold heating unit configured to heat the mold by applying second light to the mold, the second light having a light absorption rate for the mold higher than a light absorption rate for the substrate,
wherein the substrate heating unit applies the first light to the substrate such that a difference in shape between the process area and the patterned portion is reduced, and
wherein the mold heating unit applies the second light to the mold such that a difference in temperature between the mold and the substrate irradiated with the first light is smaller than a threshold value.

7. The imprint apparatus according to claim 6, wherein the mold heating unit applies light with a wavelength outside a wavelength band of light that cures the imprint material to the substrate.

8. The imprint apparatus according to claim 6, wherein the mold heating unit applies infrared rays to the mold.

9. The imprint apparatus according to claim 6,
wherein the heating unit comprises an adjusting unit configured to adjust irradiation dose of the light,
wherein the adjusting unit comprises a light modulation element and adjusts an irradiation dose distribution of the light using the light modulation element such that a difference in shape between the process area and the patterned portion is reduced, and
wherein the substrate heating unit applies the light whose dose distribution is adjusted by the adjusting unit to the substrate through the mold.

10. The imprint apparatus according to claim 6,
wherein the heating unit comprises an adjusting unit configured to adjust irradiation dose of the light,
wherein the adjusting unit comprises a plurality of light sources whose radiation can be adjusted, the adjusting unit adjusting an irradiation dose distribution of the light from the plurality of light sources such that a difference in shape between the process area and the patterned portion is reduced, and
wherein the substrate heating unit applies the light whose dose distribution is adjusted by the adjusting unit to the substrate through the mold.

11. The imprint apparatus according to claim 5, further comprising a temperature measuring unit configured to measure temperature of the process area and temperature of the patterned portion,
wherein the mold heating unit heats the mold based on the temperature of the process area and the temperature of the patterned portion measured by the temperature measuring unit in order to cause a difference in temperature between the process area and the patterned portion to be smaller than a threshold value.

12. The imprint apparatus according to claim 2, wherein the threshold value is obtained from a shape change rate of the process area permitted from alignment accuracy of the mold and the substrate and a coefficient of linear expansion of the substrate.

13. The imprint apparatus according to claim 1, wherein the mold has a coefficient of linear expansion lower than a coefficient of linear expansion of the substrate.

14. The imprint apparatus according to claim 1, further comprising a mold-shape correcting unit configured to correct a shape of the mold by applying an external force to the mold,
wherein the mold-shape correcting unit corrects the shape of the patterned portion deformed by heat by applying an external force to the mold.

15. A method of imprinting for forming a pattern of an imprint material on a process area of a substrate by using a mold including a patterned portion, the method comprising the steps of:
heating the substrate such that a difference in shape between the process area and the patterned portion is reduced; and
heating the mold such that a difference in temperature between the mold and the heated substrate is reduced.

16. A method of imprinting for forming a pattern of an imprint material on a process area of a substrate by using a mold including a patterned portion, the method comprising the steps of:
heating the mold and the substrate by applying light to the mold and the substrate,
wherein the heating step comprises causing a light absorbing portion to absorb part of the light and applying light that has passed through the light absorbing portion and the mold to the substrate, such that a difference in shape between the process area and the patterned portion is reduced and a difference in temperature between the patterned portion and the process area is smaller than a threshold value.

17. A method of imprinting for forming a pattern of an imprint material on a process area of a substrate by using a mold including a patterned portion, the method comprising the steps of:
heating the substrate by applying first light to the substrate, the first light having a light absorption rate for the substrate higher than a light absorption rate for the mold; and
heating the mold by applying second light to the mold such that a difference in temperature between the mold and the substrate irradiated with the first light is smaller than a threshold value, the second light having a light absorption rate for the mold higher than a light absorption rate for the substrate.

18. A method for producing an article, the method comprising the steps of:
forming a pattern on a substrate using an imprint apparatus: and
processing the substrate on which the pattern is formed in the forming step,
wherein the imprint apparatus is an imprint apparatus for forming a pattern of an imprint material on a process area of a substrate by using a mold including a patterned portion, the apparatus comprising:
a heating unit configured to heat the mold and the substrate,
wherein the heating unit heats the substrate such that a difference in shape between the process area and the patterned portion is reduced, and
wherein the heating unit heats the mold such that a difference in temperature between the mold and the heated substrate is reduced.

19. A mold for use in an imprint apparatus for forming a pattern of an imprint material on a substrate by using a mold including a patterned portion, the mold comprising
an absorbing portion on a surface opposite to a surface on which the patterned portion is formed, the absorbing portion being configured to absorb light to generate heat,
wherein a light absorption rate of the absorbing portion is determined based on a light absorption rate of the substrate and an irradiation dose of the light.

20. The mold according to claim 19, wherein the absorbing portion comprises a metal film containing at least one of chromium and a nickel alloy as a material.
